(19) United States
(12) Patent Application Publication
(10) Pub. No.: US 2020/0365705 A1
(43) Pub. Date: Nov. 19, 2020

(54) METHOD OF FORMING OHMIC CONTACT FOR GALLIUM NITRIDE-BASED COMPOUND SEMICONDUCTOR DEVICE AND GALLIUM NITRIDE-BASED COMPOUND SEMICONDUCTOR DEVICE

(71) Applicant: XIAMEN SANAN INTEGRATED CIRCUIT CO., LTD., XIAMEN (CN)

(72) Inventors: SHENGHOU LIU, XIAMEN (CN); GUANGYAO LIN, XIAMEN (CN); YEUK-WAH HUI, XIAMEN (CN); WENBI CAI, XIAMEN (CN)

(21) Appl. No.: 16/947,553

(22) Filed: Aug. 6, 2020

Related U.S. Application Data
(63) Continuation-in-part of application No. PCT/CN2019/073931, filed on Jan. 30, 2019.

(30) Foreign Application Priority Data
Feb. 11, 2018 (CN) 201810142648.0

(51) Int. Cl. H01L 29/45; H01L 29/40; H01L 29/20; H01L 21/24; H01L 21/285

(52) U.S. Cl. CPC H01L 29/452; H01L 29/401; H01L 21/28575; H01L 21/246; H01L 29/2003

(57) ABSTRACT

A method of forming an ohmic contact for a gallium nitride-based compound semiconductor device includes the steps of: forming a metal layered structure including a diffusion barrier layer, an aluminum layer and a metallic unit which are sequentially disposed on a GaN-based epitaxial structure; subjecting the metal layered structure to an oxidation treatment in oxygen atmosphere at 350° C. to 650° C. to obtain the oxidized metal layered structure including an aluminum oxide layer; and subjecting the oxidized metal layered structure and the GaN-based epitaxial structure to an alloying treatment in nitrogen atmosphere to form the ohmic contact therebetween. A GaN-based compound semiconductor device is also disclosed.

### CROSS-REFERENCE TO RELATED APPLICATION

This application is a bypass continuation-in-part application of PCT International Application No. PCT/CN2019/073931 filed on Jan. 30, 2019, which claims priority of Chinese Invention Patent Application No. 201810142648.0, filed on Feb. 11, 2018. The entire content of each of the international and Chinese patent applications is incorporated herein by reference.

### FIELD

The present disclosure relates to a method of forming an ohmic contact for a semiconductor device, and more particularly to a method of forming an ohmic contact for a gallium nitride (GaN)-based compound semiconductor device.

### BACKGROUND

Gallium nitride (GaN) is a third-generation semiconductor material having advantageous properties, such as a wide band gap of 3.4 eV, a high electron saturation velocity of 2×10⁷ cm/s, a high dislocation density ranging from 1×10¹⁰ V/cm to 3×10¹⁰ V/cm, great thermal conductivity, anti-corrosive ability, and radiation resistance, and thus has been widely studied due to the prospect of broad applications. In particular, high-electron-mobility transistors (HEMT) including AlGaN/GaN heterostructures, which exhibit excellent performances (such as high frequency, high power density and high operating temperature), have been actively developed for solid-state microwave devices in power electronics.

The process of forming an ohmic contact is one of the key technologies in the manufacturing of GaN-based semiconductor devices, and directly affects the performance of such devices in terms of power, frequency, and reliability. A GaN-based material, which has a high thermal stability, is not prone to chemical reactions, and hence formation of an ohmic contact thereon would be difficult. It is often required to use metallic materials having a relatively low potential barrier (such as titanium, aluminum, etc.) to conduct an alloying treatment with the GaN-based material at a high temperature (such as higher than 800° C.), so as to form the ohmic contact. However, the alloying treatment conducted at such high temperature would cause aluminum having a low melting point to be molten and diffuse outwardly. The molten aluminum might be oxidized under a high temperature and be deposited on the surface of the epitaxial structure of the GaN-based semiconductor devices, adversely changing the surface state thereof and thereby adversely affecting the performance of the semiconductor devices.

It has been reported that a silicon nitride dielectric layer grown at a high temperature as a sidewall barrier is useful to prevent the diffusion of aluminum, so as to protect the surface of the epitaxial structure and effectively reduce interfacial contamination of Al and interface state between the metallic materials and the GaN-based material. However, growth of the silicon nitride dielectric layer requires additional equipments, and an etching process is required to be further conducted on the silicon nitride dielectric layer to form vias thereon, which not only cause the manufacturing process of the GaN-based semiconductor devices to become complicated, but also incur a high manufacturing cost.

### SUMMARY

Therefore, an object of the present disclosure is to provide a method of forming an ohmic contact for a gallium nitride (GaN)-based compound semiconductor device that can alleviate at least one of the drawbacks of the prior art.

The method includes the steps of:

(a) forming a metal layered structure on a GaN-based epitaxial structure, the metal layered structure including a diffusion barrier layer, an aluminum layer and a metallic unit which are sequentially disposed on the GaN-based epitaxial structure in such order;

(b) subjecting the metal layered structure to an oxidation treatment in an oxygen atmosphere at a first temperature ranging from 350° C. to 650° C. fora first time period ranging from 30 seconds to 240 seconds so as to obtain the oxidized metal layered structure including an aluminum oxide layer formed on a lateral surface of the aluminum layer; and

(c) subjecting the oxidized metal layered structure and the GaN-based epitaxial structure to an alloying treatment in a nitrogen atmosphere at a second temperature so as to form the ohmic contact therebetween.

Another object of the present disclosure is to provide a GaN-based compound semiconductor device that can alleviate at least one of the drawbacks of the prior art.

The GaN-based compound semiconductor device includes a GaN-based epitaxial structure and a metal layered structure that is formed on the GaN-based epitaxial structure. The metal layered structure includes a diffusion barrier layer, an aluminum layer, and a metalic unit which are sequentially disposed on the GaN-based epitaxial structure in such order, and an aluminum oxide layer formed on a lateral surface of the aluminum layer. An ohmic contact is adapted to be formed between the GaN-based epitaxial structure and the metal layered structure.

### BRIEF DESCRIPTION OF THE DRAWINGS

Other features and advantages of the present disclosure will become apparent in the following detailed description of the embodiments with reference to the accompanying drawings, of which:

FIG. 1 is a schematic view illustrating consecutive steps of an embodiment of a method of forming an ohmic contact for a gallium nitride (GaN)-based compound semiconductor device according to the present disclosure; and

FIG. 2 are scanning electron microscopy images respectively showing the ohmic contact formed by the embodiment according to the present disclosure and that formed by a conventional method.

### DETAILED DESCRIPTION

Before the present disclosure is described in greater detail, it should be noted that where considered appropriate, reference numerals or terminal portions of reference numerals have been repeated among the figures to indicate corresponding or analogous elements, which may optionally have similar characteristics.

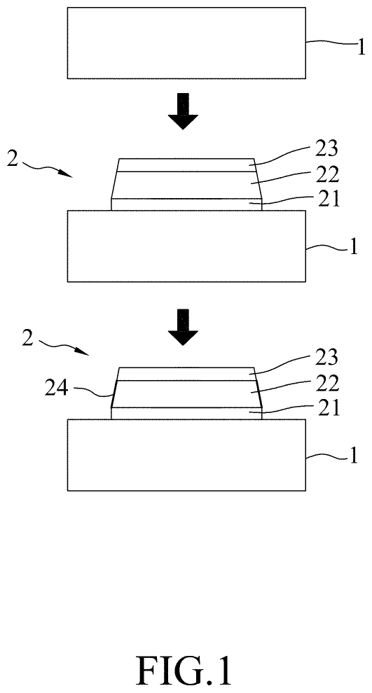

Referring to FIG. 1, an embodiment of a method of forming an ohmic contact for a gallium nitride (GaN)-based compound semiconductor device according to the present disclosure includes steps (a) to (c).

In step (a), a metal layered structure 2 is formed on a GaN-based epitaxial structure 1. The metal layered structure 2 includes a diffusion barrier layer 21, an aluminum layer 22, and a metallic unit 23 which are sequentially disposed on the GaN-based epitaxial structure 1 in such order.

The diffusion barrier layer 21 may be made of Ti, and may have a thickness ranging from 10 nm to 30 nm. The aluminum layer 22 may have a thickness ranging from 100 nm to 200 nm. The metallic unit 23 may include at least one metallic layer. Examples of the metallic layer may include, but are not limited to, a Ni layer, an Au layer, a Ti layer, a Pd layer, a Pt layer, a Mo layer, and a TiN layer. For instance, the metallic unit 23 may include the TiN layer. For another instance, the metallic unit 23 may include multiple metallic layers such as Ni/Au layers, Ti/Au layers, Pd/Au layers, Pt/Au layers, or Mo/Au layers. Each layer of the metal layered structure 2 may be formed by a metal evaporation process or a sputtering process. The resultant metal layered structure 2 may be further subjected to a lift off process to form a predetermined pattern.

In step (b), the metal layered structure 2 is subjected to an oxidation treatment in an oxygen atmosphere at a first temperature ranging from 350° C. to 650° C. for a first time period ranging from 30 seconds to 240 seconds, so as to obtain the oxidized metal layered structure 2 including an aluminum oxide layer 24 that is formed on a lateral surface of the aluminum layer 22.

The first temperature and the first time period may be adjusted according to the oxidation degree of the metal layered structure 2 to be achieved. For example, the first temperature may range from 400° C. to 600° C., and the first time period may range from 50 seconds to 150 seconds.

In this embodiment, step (b) includes sub-steps (b1) and (b2). In sub-step (b1), the metal layered structure 2 is heated from a room temperature (about 20° C. to 30° C.) to the first temperature within 30 seconds to 180 seconds, followed by maintaining the first temperature for the first time period to conduct the oxidation treatment. In sub-step (b2), the oxidized metal layered structure 2 is cooled from the first temperature to less than 50° C. Examples of a process for cooling the oxidized metal layered structure 2 may include, but are not limited to, a water cooling process, an air cooling process, a natural cooling process, and combinations thereof.

In step (c), the oxidized metal layered structure 2 and the GaN-based epitaxial structure 1 are subjected to an alloying treatment in a nitrogen atmosphere at a second temperature that is higher than the first temperature so as to form the ohmic contact therebetween.

The alloying treatment may be conducted at the second temperature that ranges from 800° C. to 900° C. for a second time period that ranges from 20 seconds to 60 seconds. The alloying treatment may be conducted using a rapid thermal annealing process.

The second temperature and the second time period of the alloying treatment may be predetermined based on a minimum resistivity of the thus formed ohmic contact to be achieved. Due to the formation of the aluminum oxide layer on the lateral surface of the aluminum layer 22, molten aluminum can be effectively prevented from being diffused to and deposited on a surface of the GaN-based epitaxial structure 1 during the alloying treatment, thereby improving the reliability of the GaN-based compound semiconductor device.

The present disclosure also provides the GaN-based compound semiconductor device, which may be manufactured by the abovementioned steps (a) and (b). The GaN-based compound semiconductor device includes the GaN-based epitaxial structure 1 and the metal layered structure 2 that is formed on the GaN-based epitaxial structure 1. The metal layered structure 2 includes the diffusion barrier layer 21, the aluminum layer 22, and the metallic unit 23 which are sequentially disposed on the GaN-based epitaxial structure 1 in such order, and the aluminum oxide layer 24 formed on the lateral surface of the aluminum layer 22. The ohmic contact is adapted to be formed between the GaN-based epitaxial structure 1 and the metal layered structure 2 by conducting the abovementioned step (c) of the method according to this disclosure.

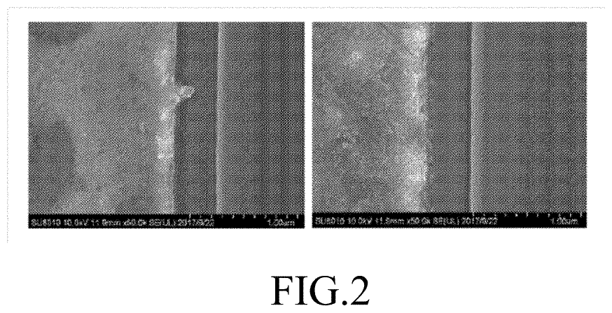

FIG. 2 shows scanning electron microscopy images of the ohmic contact formed by the method of the present disclosure (right panel) and that formed by a conventional method (left panel). The conventional method of forming an ohmic contact is different from the method of the present disclosure in that the oxidation treatment of the metal layered structure 2 (i.e., step (b)) is omitted. In the left panel, metal burrs are observed due to lateral diffusion of molten aluminum during the alloying treatment (namely, the conventional method cannot lead to formation of the aluminum oxide layer 24, which can block such diffusion, on the lateral surface of the aluminum layer 22). In contrast, in the right panel, metal burrs are clearly absent since the aluminum oxide layer 24 formed on the lateral surface of the aluminum layer 22 is capable of blocking the diffusion of aluminum. Therefore, the ohmic contact formed by the method of the present disclosure is expected to be suitable for fabricating source and drain metal electrodes of the GaN-based compound semiconductor device, so as to reduce the risk of tip discharge caused by metal burrs, thereby improving breakdown voltage of the GaN-based compound semiconductor device according to the present disclosure.

In summary, by virtue of formation of the aluminum oxide layer 24 on the lateral surface of the aluminum layer 22, which is conducted at a temperature lower than that of the subsequent alloying treatment, the method of this disclosure is capable of preventing the problem of lateral diffusion of molten aluminum during the alloying treatment, so as to not only effectively reduce the risk of interfacial contamination of aluminum and change in the interface state between the GaN-based epitaxial structure 1 and the metal layered structure 2, but also simplify the manufacturing process and greatly save the manufacturing cost. In addition, the GaN-based compound semiconductor device having the ohmic contact formed thereby without metal burrs can exhibit non-interfered electrical properties, possessing satisfactory reliability.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the present disclosure has been described in connection with what is considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A method of forming an ohmic contact for a gallium nitride (GaN)-based compound semiconductor device, comprising the steps of:
(a) forming a metal layered structure on a GaN-based epitaxial structure, the metal layered structure including a diffusion barrier layer, an aluminum layer and a metallic unit which are sequentially disposed on the GaN-based epitaxial structure in such order;
(b) subjecting the metal layered structure to an oxidation treatment in an oxygen atmosphere at a first temperature ranging from 350° C. to 650° C. fora first time period ranging from 30 seconds to 240 seconds so as to obtain the oxidized metal layered structure including an aluminum oxide layer formed on a lateral surface of the aluminum layer; and
(c) subjecting the oxidized metal layered structure and the GaN-based epitaxial structure to an alloying treatment in a nitrogen atmosphere at a second temperature that is higher than the first temperature so as to form the ohmic contact therebetween.

2. The method as claimed in claim 1, wherein the diffusion barrier layer is made of Ti.

3. The method as claimed in claim 1, wherein the diffusion barrier layer has a thickness that ranges from 10 nm to 30 nm.

4. The method as claimed in claim 1, wherein the aluminum layer has a thickness that ranges from 100 nm to 200 nm.

5. The method as claimed in claim 1, wherein the metallic unit includes at least one metallic layer selected from the group consisting of a Ni layer, a Au layer, a Ti layer, a Pd layer, a Pt layer, a Mo layer, and a TiN layer.

6. The method as claimed in claim 1, wherein the metal layered structure is formed by one of a metal evaporation process and a sputtering process.

7. The method as claimed in claim 1, wherein in step (b), the first temperature ranges from 400° C. to 600° C. and the first time period ranges from 50 seconds to 150 seconds.

8. The method as claimed in claim 1, wherein step (b) includes the sub-steps of:
(b1) heating the metal layered structure to the first temperature within 30 seconds to 180 seconds, followed by maintaining the first temperature for the first time period to conduct the oxidation treatment; and
(b2) cooling the oxidized metal layered structure from the first temperature to less than 50° C.

9. The method as claimed in claim 8, wherein in sub-step (b2), the cooling is conducted by a process selected from the group consisting of a water cooling process, an air cooling process, a natural cooling process, and combinations thereof.

10. The method as claimed in claim 1, wherein in step (c), the alloying treatment is conducted using a rapid thermal annealing process.

11. The method as claimed in claim 1, wherein in step (c), the second temperature ranges from 800° C. to 900° C.

12. The method as claimed in claim 11, wherein in step (c), the alloying treatment is conducted for a second time period that ranges from 20 seconds to 60 seconds.

13. A GaN-based compound semiconductor device, comprising:
a GaN-based epitaxial structure; and
a metal layered structure that is formed on said GaN-based epitaxial structure, and that includes a diffusion barrier layer, an aluminum layer and a metallic unit which are sequentially disposed on said GaN-based epitaxial structure in such order, and an aluminum oxide layer which is formed on a lateral surface of said aluminum layer, an ohmic contact adapted to be formed between said GaN-based epitaxial structure and said metal layered structure.

14. The GaN-based compound semiconductor device as claimed in claim 13, wherein said diffusion barrier layer is made of Ti.

15. The GaN-based compound semiconductor device as claimed in claim 13, wherein said diffusion barrier layer has a thickness that ranges from 10 nm to 30 nm.

16. The GaN-based compound semiconductor device as claimed in claim 13, wherein said aluminum layer has a thickness that ranges from 100 nm to 200 nm.

17. The GaN-based compound semiconductor device as claimed in claim 13, wherein said metallic unit includes at least one metallic layer selected from the group consisting of a Ni layer, a Au layer, a Ti layer a Pd layer, a Pt layer, a Mo layer, and a TiN layer.
